(19) United States
(12) Patent Application Publication
(10) Pub. No.: US 2014/0346452 A1
(43) Pub. Date: Nov. 27, 2014

(54) ORGANIC LIGHT-EMITTING DISPLAY APPARATUS AND METHOD OF MANUFACTURING THE SAME

(71) Applicant: Samsung Display Co., Ltd., Yongin-city (KR)

(72) Inventors: Chun-Gi You, Yongin-city (KR); Jun-Hoo Choi, Yongin-city (KR)

(73) Assignee: Samsung Display Co., Ltd., Yongin-city (KR)

(21) Appl. No.: 14/034,914

(22) Filed: Sep. 24, 2013

(30) Foreign Application Priority Data
May 21, 2013 (KR) 10-2013-0057295

(51) Int. Cl. H01L 27/32

(52) U.S. Cl. CPC H01L 27/3258
USPC 257/40; 438/29

(57) ABSTRACT

An organic light-emitting display apparatus includes a substrate; an active layer disposed on the substrate; a gate electrode disposed so as to be insulated from the active layer and to correspond to a part of the active layer; a source electrode including a first source electrode layer connected to the active layer, and a second source electrode layer connected to the first source electrode layer and is larger than the first source electrode layer; a drain electrode including a first drain electrode layer connected to the active layer, and a second drain electrode layer connected to the first drain electrode layer and is larger than the first drain electrode layer; a pixel electrode electrically connected to at least one of the source electrode or the drain electrode; and a color filter disposed between the substrate and the pixel electrode.

### CROSS-REFERENCE TO RELATED APPLICATIONS

This application claims the benefit of Korean Patent Application No. 10-2013-0057295, filed on May 21, 2013 in the Korean Intellectual Property Office, the disclosure of which is incorporated herein in its entirety by reference.

### BACKGROUND

1. Field

The present disclosure relates to an organic light-emitting display apparatus that is capable of simplifying and facilitating a manufacturing process and has an improved image quality, and a method of manufacturing the organic light-emitting display apparatus.

2. Description of the Related Technology

Organic light-emitting display apparatuses are display apparatuses including an organic light-emitting device in a display area thereof. The organic light-emitting device includes a pixel electrode and a counter electrode that are opposite to each other, and an intermediate layer interposed between the pixel electrode and the counter electrode which includes an emission layer.

Such organic light-emitting display apparatuses are classified into active matrix type organic light-emitting display apparatuses and passive matrix type organic light-emitting display apparatuses, according to their respective driving method. In the active matrix type organic light-emitting display apparatus, controlling whether each sub-pixel emits light is performed through a thin film transistor (TFT) provided in each sub-pixel, while in the passive matrix type organic light-emitting display apparatus, controlling whether each sub-0pixel emits light is performed through electrodes that are arranged in a matrix. In the active matrix type organic light-emitting display apparatus, an organic light-emitting device is generally located on a TFT, and various films or layers such as a gate insulating layer or an insulating interlayer are used to form the TFT.

### SUMMARY OF CERTAIN INVENTIVE ASPECTS

Embodiments of the present invention provide an organic light-emitting display apparatus that is capable of simplifying and facilitating a manufacturing process and has an improved image quality, and a method of manufacturing the organic light-emitting display apparatus.

According to an aspect of the present invention, there is provided an organic light-emitting display apparatus including: a substrate; an active layer disposed on the substrate; a gate electrode insulated from the active layer and configured to correspond to a part of the active layer; a source electrode including a first source electrode layer connected to the active layer and a second source electrode layer connected to the first source electrode layer, the second source electrode layer being larger than the first source electrode layer; a drain electrode including a first drain electrode layer connected to the active layer and a second drain electrode layer connected to the first drain electrode layer, the second drain electrode layer being larger than the first drain electrode layer; a pixel electrode electrically connected to any one of the source electrode and the drain electrode; and a color filter interposed between the substrate and the pixel electrode.

In addition, the organic light-emitting display apparatus may further include a first insulating interlayer covering the gate electrode and having a first contact hole; and a second insulating interlayer disposed on the first insulating interlayer and having a second contact hole.

In this case, the first source electrode layer and the first drain electrode layer correspond to the first contact hole, and the second source electrode layer and the second drain electrode layer correspond to the second contact hole.

A size of the first contact hole may be smaller than a size of the second contact hole.

The first insulating interlayer may include an inorganic material, and the second insulating interlayer may include an organic material.

The first insulating interlayer may have an opening corresponding to the pixel electrode, the color filter is located within the opening, and the pixel electrode may be disposed on the second insulating interlayer. In this case, a surface of the second insulating interlayer contacting the color filter may have a concave shape toward the inside of the second insulating interlayer.

A top surface of the second insulating interlayer may be planar.

Meanwhile, the organic light-emitting display apparatus may further include a first insulating interlayer covering the gate electrode and having a plurality of first contact holes; and a second insulating interlayer disposed on the first insulating interlayer and having a second contact hole connected to the plurality of first contact holes.

The organic light-emitting display apparatus may further include a capacitor including a first capacitor electrode and a second capacitor electrode that are both disposed on the substrate.

In this case, the organic light-emitting display apparatus may further include a first insulating interlayer covering the gate electrode; and a second insulating interlayer disposed on the first insulating interlayer, and the first insulating interlayer and the second insulating interlayer may each have an opening portion corresponding to the capacitor.

The organic light-emitting display apparatus may further include at least one of a data wiring or a power wiring disposed on the capacitor so as to correspond to the capacitor. One or more insulating layers may be interposed between at least one of the data wiring and the power wiring, and the capacitor. Alternatively, the organic light-emitting display apparatus may further include a first insulating interlayer covering the gate electrode; and a second insulating interlayer disposed on the first insulating interlayer, and the first insulating interlayer and the second insulating interlayer may both be interposed between the capacitor and the power wiring.

The organic light-emitting display apparatus may further include a data wiring disposed on the capacitor and corresponding to the capacitor. In this case, one or more insulating layers may be interposed between the capacitor and the data wiring.

Meanwhile, the organic light-emitting display apparatus may further include a first insulating interlayer covering the gate electrode; and a second insulating interlayer disposed on the first insulating interlayer, and the first insulating interlayer and the second insulating interlayer may both be interposed between the capacitor and the data wiring.

Alternatively, the organic light-emitting display apparatus may further include a power wiring and a data wiring both disposed on the capacitor and corresponding to the capacitor, wherein the power wiring and the data wiring may be disposed in different layers so as to overlap each other.

In this case, the organic light-emitting display apparatus may further include a first insulating interlayer covering the gate electrode; and a second insulating interlayer disposed on the first insulating interlayer, and the power wiring may be disposed on the first insulating interlayer, wherein the data wiring may be disposed on the second insulating interlayer. Alternatively, the organic light-emitting display apparatus may further include a first insulating interlayer covering the gate electrode; and a second insulating interlayer disposed on the first insulating interlayer, and the data wiring may be disposed on the first insulating interlayer, wherein the power wiring may be disposed on the second insulating interlayer.

The first capacitor electrode and the active layer may be disposed on the same layer, and the second capacitor electrode and the gate electrode may be disposed on the same layer.

The pixel electrode may be disposed on the same layer as at least a part of the second source electrode layer and at least a part of the second drain electrode layer.

The gate electrode may include a first conductive layer and a second conductive layer disposed on the first conductive layer, and the first capacitor electrode may include the same material as the first conductive layer and is disposed on the same layer as the first conductive layer.

According to another aspect of the present invention, there is provided a method of manufacturing an organic light-emitting display apparatus, the method including: forming an active layer on a substrate; forming a gate electrode configured to be insulated from the active layer and to overlap the active layer; forming a color filter on the substrate; forming a source electrode including a first source electrode layer connected to the active layer and a second source electrode layer connected to the first source electrode layer, the second source electrode layer being larger than the first source electrode layer; forming a drain electrode including a first drain electrode layer connected to the active layer and a second drain electrode layer connected to the first drain electrode layer, the second drain electrode layer being larger than the first drain electrode layer; and forming a pixel electrode electrically connected to any one of the source electrode and the drain electrode and corresponding to a color filter.

The method may further include forming a first insulating interlayer having a first contact hole configured to cover the gate electrode, and a second insulating interlayer disposed on the first insulating interlayer and having a second contact hole.

The forming of the source electrode and the forming of the drain electrode include forming the first source electrode layer and the first drain electrode layer so as to correspond to the first contact hole, and forming the second source electrode layer and the second drain electrode layer so as to correspond to the second contact hole.

In this case, the forming of the source electrode and the forming of the drain electrode may include simultaneously forming the first source electrode layer, the first drain electrode layer, the second source electrode layer, and the second drain electrode layer.

The forming of the second insulating interlayer may include: forming a first insulating interlayer configured to cover the gate electrode; forming a first contact hole configured to expose a part of the active layer and an opening corresponding to an area where the pixel electrode is to be formed, in the first insulating interlayer; forming a second insulating interlayer configured to cover the first insulating interlayer; and forming a second contact hole configured to expose a part of the active layer in the second insulating interlayer. The forming of the color filter may include forming the color filter within the opening of the first insulating interlayer, and the forming of the second insulating interlayer may include forming the second insulating interlayer so as to cover the color filter.

### BRIEF DESCRIPTION OF THE DRAWINGS

The above and other features and advantages of the present invention will become more apparent by describing in detail certain embodiments thereof with reference to the attached drawings in which:

FIG. 1 is a schematic cross-sectional view illustrating an organic light-emitting display apparatus according to an embodiment of the present invention;

FIG. 2 is a detailed plan view illustrating a portion “A” of FIG. 1;

FIGS. 3 through 10 are schematic cross-sectional views illustrating processes of a method of manufacturing an organic light-emitting display apparatus according to another embodiment of the present invention;

FIGS. 11 through 13 are schematic cross-sectional views illustrating processes of a method of manufacturing an organic light-emitting display apparatus according to another embodiment of the present invention; and

FIG. 14 is a schematic cross-sectional view illustrating an organic light-emitting display apparatus according to another embodiment of the present invention.

### DETAILED DESCRIPTION OF CERTAIN INVENTIVE EMBODIMENTS

The present invention will now be described more fully with reference to the accompanying drawings, in which certain embodiments of the invention are shown. The invention may, however, be embodied in many different forms, and should not be construed as being limited to the embodiments set forth herein; rather, these embodiments are provided so that this disclosure will be thorough and complete, and will fully convey the concept of the invention to one of ordinary skill in the art. In the drawings, the thicknesses of layers and regions may be exaggerated for clarity. As used herein, the term “and/or” includes any and all combinations of one or more of the associated listed items. Expressions such as “at least one of,” when preceding a list of elements, modify the entire list of elements and do not modify the individual elements of the list.

In the following embodiments, an x-axis, a y-axis, and a z-axis are not limited to three axes on an orthogonal coordinates system, and may be construed as a broad sense including this. For example, the x-axis, the y-axis, and the z-axis may be perpendicular to each other, or may refer to different directions that are not perpendicular to each other.

It will also be understood that when an element such as a layer, region, or substrate is referred to as being “on” another element, it may be directly on the other element, or intervening elements may also be present.

A conventional organic light-emitting display apparatus has a problem in that a short defect may occur between a gate electrode and a source electrode or between the gate electrode and a drain electrode, due to the inflow of particles when forming various films or layers during a manufacturing process, morphology of a member that is formed under the various films or layers, for example, morphology of the gate electrode or the like, or due to other factors. In particular, when a high-resolution organic light-emitting display apparatus is manufactured, line widths of wirings and intervals between the wirings are narrowed, and thus the above-mentioned problem frequently occurs, which results in a limitation in terms of improving the image quality of the organic light-emitting display apparatus.

FIG. 1 is a schematic cross-sectional view illustrating an organic light-emitting display apparatus 100 according to an embodiment of the present invention.

Referring to FIG. 1, the organic light-emitting display apparatus 100 may include a substrate 101, a buffer layer 102, a gate insulating layer 104, a pixel electrode 108, a thin film transistor TFT, an intermediate layer 140, a counter electrode 150, a first insulating interlayer 109, a second insulating interlayer 119, a pixel definition layer 130, and a capacitor 110.

The substrate 101 may have a plurality of areas, for example, an emission area PA, a transistor area TA, and a storage area SA.

The emission area PA of the substrate 101 is an area where at least the intermediate layer 140 is disposed and visible light emitted from the intermediate layer 140 may reach or pass therethrough. The transistor area TA is an area where various electrical signals for controlling whether emission occurs in the emission area PA and for controlling the degree of the emission in the emission area PA are generated and/or transmitted. The thin film transistor TFT may be disposed in the transistor area TA.

The thin film transistor TFT includes an active layer 103, a gate electrode 107, a source electrode 111, and a drain electrode 112. In addition, the source electrode 111 includes a first source electrode layer 111a and a second source electrode layer 111b, and the drain electrode 112 includes a first drain electrode layer 112a and a second drain electrode layer 112b.

The capacitor 110 is disposed in the storage area SA. The capacitor 110 includes a first capacitor electrode 113 and a second capacitor electrode 117.

The substrate 101 including the emission area PA, the transistor area TA, and the storage area SA may be a SiO₂-based translucent glass material, but the present invention is not limited thereto. That is, the substrate 101 may be formed of any material as long as the material has a translucent property, for example, a translucent plastic material.

The buffer layer 102 is formed on the substrate 101. The buffer layer 102 may prevent impurities from penetrating the active layer 103 or the like. The buffer layer 102 may include an inorganic material such as silicon oxide, silicon nitride, silicon oxynitride, aluminum oxide, aluminum nitride, titanium oxide, or titanium nitride, or an organic material such as polyimide, polyester, or acryl. In addition, the buffer layer 102 may be a single layer or may be a stack of a plurality of layers.

The active layer 103 and the first capacitor electrode 113 may be disposed on the buffer layer 102, and specifically, the active layer 103 may be disposed in the transistor area TA and the first capacitor electrode 113 may be disposed in the storage area SA. The active layer 103 and the first capacitor electrode 113 may include the same material. For example, the active layer 103 and the first capacitor electrode 113 may include a material such as semiconductor silicon.

The gate insulating layer 104 is disposed on the buffer layer 102 so as to cover the active layer 103 and the first capacitor electrode 113. The gate electrode 107 and the second capacitor electrode 117 are disposed on the gate insulating layer 104.

The gate electrode 107 may include a first conductive layer 105 and a second conductive layer 106. The first conductive layer 105 may be formed so as to be thinner than the second conductive layer 106. The first conductive layer 105 may include, for example, ITO, IZO, ZnO, In₂O₃, IGO, or AZO, but the present invention is not limited thereto. As long as the first conductive layer 105 is formed to have such a thickness that a dopant may pass during a doping process, the first conductive layer 105 may include Mo, MoW, an Al-based alloy, or the like. The second conductive layer 106 may be disposed on the first conductive layer 105, may include a metal or a metal alloy such as Mo, MoW, or an Al-based alloy, and may have a single-layered structure or a multi-layered structure. The second conductive layer 106 may have, for example, a stacked structure of Mo/Al/Mo.

The second capacitor electrode 117 and the first conductive layer 105 may be disposed on the same layer and may include the same material. That is, the second capacitor electrode 117 and the first conductive layer 105 of the gate electrode 107 may be simultaneously formed.

The first insulating interlayer 109 is formed on the gate insulating layer 104 so as to cover the gate electrode 107 and the second capacitor electrode 117. The first insulating interlayer 109 may be formed so as to include various insulating materials, and may preferably include an inorganic material. The first insulating interlayer 109 includes a first contact hole 109c, an opening portion 109a, and an opening 109b.

The first contact hole 109c of the first insulating interlayer 109 exposes a part of the active layer 103 in the transistor area TA. The opening portion 109a of the first insulating interlayer 109 exposes at least one area of a top surface of the second capacitor electrode 117 in the storage area SA. The opening 109b of the first insulating interlayer 109 is located in the emission area PA so that a color filter CF_{R} is located within the opening 109b. The first source electrode layer 111a of the source electrode 111 and the first drain electrode layer 112a of the drain electrode 112 are disposed so as to correspond to the first contact hole 109c of the first insulating interlayer 109. Specifically, the first source electrode layer 111a and the first drain electrode layer 112a are formed so as to be connected to the active layer 103 through the first contact hole 109c. The first source electrode layer 111a and the first drain electrode layer 112a may include various materials, for example, a metal such as Au, Pd, Pt, Ni, Rh, Ru, Ir, Os, Al, Mo, Nd, Mo, W, or an alloy containing at least two of these materials.

The color filter CF_{R} is located within the opening 109b of the first insulating interlayer 109. The color filter CF_{R} is located on an optical path in which light emitted from the intermediate layer 140 passes to the outside through the substrate 101, so that light having a predetermined wavelength passes to the outside of the substrate 101. The color filter CF_{R} is located within the opening 109b of the first insulating interlayer 109, but the present invention is not limited thereto. As shown in FIG. 1, openings are formed in the buffer layer 102 or the gate insulating layer 104 below the first insulating interlayer 109, and thus the color filter CF_{R} may also be located within the openings. That is, the color filter CF_{R} may be disposed between the substrate 101 and the pixel electrode 108.

The second insulating interlayer 119 is disposed on the insulating interlayer 109 so as to cover the color filter CF_{R}. The second insulating interlayer 119 may include various insulating materials, and may preferably include an organic material. As shown in FIG. 1, the color filter CF_{R} may be formed in such a way that the top surface thereof is formed convex during the formation process thereof. Thus, a surface of the second insulating interlayer 119 which comes into contact with the color filter CF_{R} may be formed concave toward the inside of the second insulating interlayer 119.

The second insulating interlayer 119 includes a second contact hole 119c. In addition, the second insulating interlayer 119 is disposed so as not to cover at least one area of the top surface of the second capacitor electrode 117. Specifically, the second insulating interlayer 119 may include an opening portion 119a that overlaps the top surface of the second capacitor electrode 117.

The second source electrode layer 111b of the source electrode 111 and the second drain electrode layer 112b of the drain electrode 112 are disposed so as to correspond to the second contact hole 119c of the second insulating interlayer 119. That is, the second source electrode layer 111b may be connected to the first source electrode layer 111a, and the second drain electrode layer 112b may be connected to the first drain electrode layer 112a. The second source electrode layer 111b and the second drain electrode layer 112b may include various materials, for example, a metal such as Au, Pd, Pt, Ni, Rh, Ru, Ir, Os, Al, Mo, Nd, Mo, W, or an alloy containing at least two of these materials.

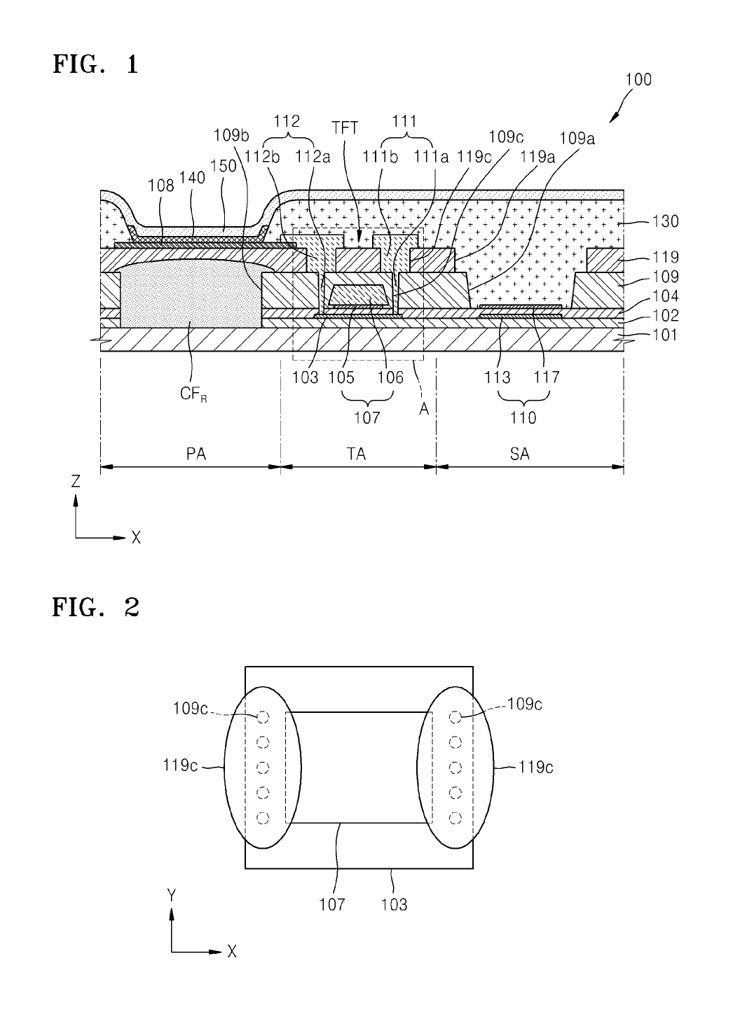

The first source electrode layer 111a of the source electrode 111 may be smaller than the second source electrode layer 111b. Specifically, the first contact hole 109c of the first insulating interlayer 109 may be smaller than the second contact hole 119c of the second insulating interlayer 119, the first source electrode layer 111a may correspond to the first contact hole 109c, and the second source electrode layer 111b may correspond to the second contact hole 119c. In addition, as shown in FIG. 2, a plurality of the first contact holes 109c may be located to be connected to one second contact hole 119c when needed, so that a plurality of the first source electrode layers 111a may be disposed to be connected to the second source electrode layer 111b.

The first drain electrode layer 112a of the drain electrode 112 may be smaller than the second drain electrode layer 112b. Specifically, the first contact hole 109c of the first insulating interlayer 109 may be smaller than the second contact hole 119c of the second insulating interlayer 119, the first drain electrode layer 112a may correspond to the first contact hole 109c, and the second drain electrode layer 112b may correspond to the second contact hole 119c. In addition, as shown in FIG. 2, a plurality of the first contact holes 109c may be located to be connected to one second contact hole 119c, so that a plurality of the first drain electrode layers 112a may be disposed to be connected to the second drain electrode layer 112b.

As a result, in the organic light-emitting display apparatus, two insulating interlayers 109 and 119 may be interposed between the gate electrode 107, and the second source electrode layer 111b and second drain electrode layer 112b so as to effectively prevent a short defect from occurring between the gate electrode 107 and the second source electrode layer 111b and/or between the gate electrode 107 and the second drain electrode layer 112b due to foreign substances generated between the gate electrode 107 and the second source electrode layer 111b and/or between the gate electrode 107 and the second drain electrode layer 112b, or metal materials remaining when forming the gate electrode 107 and the second source electrode layer 111b and/or the gate electrode 107 and the second drain electrode layer 112b.

In particular, the first insulating interlayer 109 containing an inorganic material having excellent water resistance and excellent step coverage may be disposed on the gate electrode 107 so as to effectively insulate the gate electrode 107 from the source electrode 111 and/or the drain electrode 112. In addition, the second insulating interlayer 119 containing an organic material is disposed on the first insulating interlayer 109, and thus the second insulating interlayer 119 may be easily formed to have a desired thickness. In addition, the top surface of the second insulating interlayer 119 may be formed flat, so that the second insulating interlayer 119 may also serve as a planarization layer.

Since the first contact hole 109c of the first insulating interlayer 109 is smaller than the second contact hole 119c, an interval between the source electrode 111 and the drain electrode 112 and intervals between other wirings are minimized, thereby allowing the high-resolution organic light-emitting display apparatus 100 to be realized. In addition, since the second contact hole 119c of the second insulating interlayer 119 is larger than the first contact hole 109c, an electrical property of the thin film transistor TFT may be improved. In particular, when a plurality of the first contact holes 109c are connected to one second contact hole 119c, an electrical contact property between the first source electrode layer 111a and the active layer 103 and an electrical contact property between the first drain electrode layer 112a and the active layer 103 may be preferably improved.

The pixel electrode 108 is located on the second insulating interlayer 119 so that at least a part of the pixel electrode 108 is located in the emission area PA. Thus, the color filter CF_{R} may be located between the pixel electrode 108 and the substrate 101. The pixel electrode 108 includes a transmissive conductive material, for example, ITO, IZO, ZnO, In₂O₃, IGO, or AZO. An end of the pixel electrode 108 is electrically connected to the second drain electrode layer 112b so as to be covered by the second drain electrode layer 112b or to come into contact with the second drain electrode layer 112b, thereby allowing the pixel electrode 108 to receive an electrical signal from the second drain electrode layer 112b.

The pixel definition layer 130 may cover the second source electrode layer 111b of the source electrode 111, the second drain electrode layer 112b of the drain electrode 112, and the second capacitor electrode 117. The pixel definition layer 130 may not cover at least a central portion of the top surface of the pixel electrode 108.

The intermediate layer 140 has a multi-layered structure including an emission layer, and may be disposed on the pixel electrode 108. Specifically, the intermediate layer 140 may be disposed on a portion that is not covered by the pixel definition layer 130 of the pixel electrode 108. Although the intermediate layer 140 is located only on the pixel electrode 108 in FIG. 1, the present invention is not limited thereto. For example, a part of the intermediate layer 140 may be disposed as a common layer across a display area of the organic light-emitting display apparatus, or another part thereof may be disposed so as to correspond to the pixel electrode 108.

The intermediate layer 140 may include a low or high molecular material. When the intermediate layer 140 is formed of a low molecular material, a hole injection layer (HIL), a hole transport layer (HTL), an emission layer (EML), an electron transport layer (ETL), and an electron injection layer (EIL), and the like may be formed to have a single-layered structure or a multi-layered structure. Examples of available organic materials may include copper phthalocyanine (CuPc), N,N′-di(naphthalene-1-yl)-N,N′-diphenyl-benzidine (NPB), tris-8-hydroxyquinoline aluminum (Alq3), and the like. These layers may be formed by vacuum deposition, laser induced thermal imaging (LITI), or the like.

When the intermediate layer 140 is formed of a high molecular material, the intermediate layer 140 may have a structure including an HTL and an EML. Poly-(3,4-ethylene-dihydroxy thiophene (PEDOT) or polyaniline (PANT) may be used as the HTL, and a poly-phenylenevinylene (PPV)-based high molecular material or a polyfluorene-based high molecular material may be used as the EML. These layers may be formed by screen printing, ink jet printing, LITI, or the like.

The intermediate layer 140 is not limited thereto, and may have any of various structures.

The counter electrode 150 may be disposed on the intermediate layer 140. The counter electrode 150 may include a metal such as Ag, Mg, Al, Pt, Pd, Au, Ni, Nd, Ir, Cr, Li, or Ca. In addition, the counter electrode 150 may include ITO, IZO, ZnO, or In₂O₃ so as to be capable of light transmission when necessary.

In the organic light-emitting display apparatus 100, two insulating interlayers 109 and 119 are interposed between the gate electrode 107, and the second source electrode layer 111b and second drain electrode layer 112b so as to effectively prevent a short defect from occurring between the gate electrode 107 and the second source electrode layer 111b and/or between the gate electrode 107 and the second drain electrode layer 112b. Thus, the image quality of the organic light-emitting display apparatus 100 is improved.

In particular, the first contact hole 109c of the first insulating interlayer 109 is formed to be smaller than the second contact hole 119c so as to minimize an interval between the source electrode 111 and the drain electrode 112 and intervals between other wirings, thereby realizing the high-resolution organic light-emitting display apparatus 100. In addition, the second contact hole 119c of the second insulating interlayer 119 is formed to be larger than the first contact hole 109c, thereby improving an electrical property of the thin film transistor TFT.

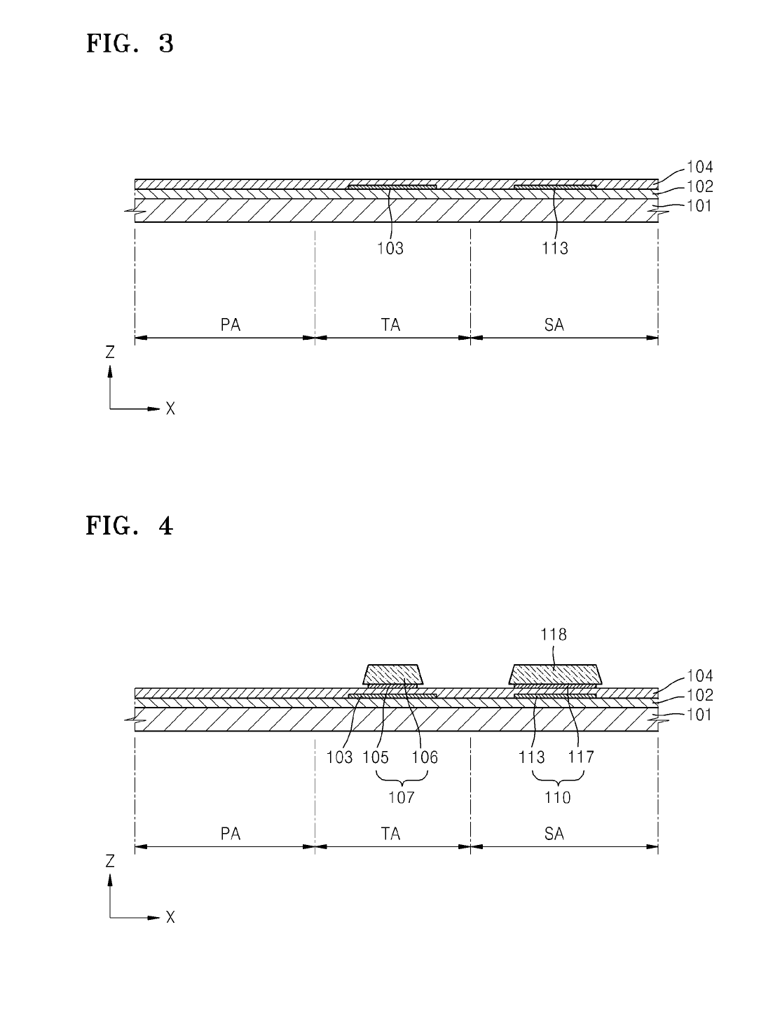

FIGS. 3 through 10 are schematic cross-sectional views illustrating processes of a method of manufacturing an organic light-emitting display apparatus according to another embodiment of the present invention.

First, as shown in FIG. 3, the substrate 101 is prepared. Then, the buffer layer 102 is formed on the substrate 101, and the active layer 103 and the first capacitor electrode 113 are formed on the buffer layer 102. The first capacitor electrode 113 and the active layer 103 may be formed of the same material. In addition, the first capacitor electrode 113 and the active layer 103 may be simultaneously formed through a patterning processing using one mask. Then, the gate insulating layer 104 is formed on the buffer layer 102 so as to cover the active layer 103 and the first capacitor electrode 113.

Subsequently, as shown in FIG. 4, the gate electrode 107 and the second capacitor electrode 117 are formed on the gate insulating layer 104. Specifically, a first conductive layer is formed on the gate insulating layer 104, and a second conductive layer is formed on the first conductive layer, and then the gate electrode 107 is formed by simultaneously patterning the first and second conductive layers. In this process, the second capacitor electrode 117 and the cover layer 118 provided thereon may be simultaneously formed. That is, the first conductive layer 105 of the gate electrode 107 and the second capacitor electrode 117 may be formed of the same material, and the second conductive layer 106 of the gate electrode 107 and the cover layer 118 may be formed of the same material. A process of doping a portion that is not blocked by the gate electrode 107 of the active layer 103 with impurities may be performed using the gate electrode 107 as a mask.

The first conductive layer may be formed to have a thickness that is smaller than that of the second conductive layer in order to dope the first capacitor electrode 113 later through the second capacitor electrode 117.

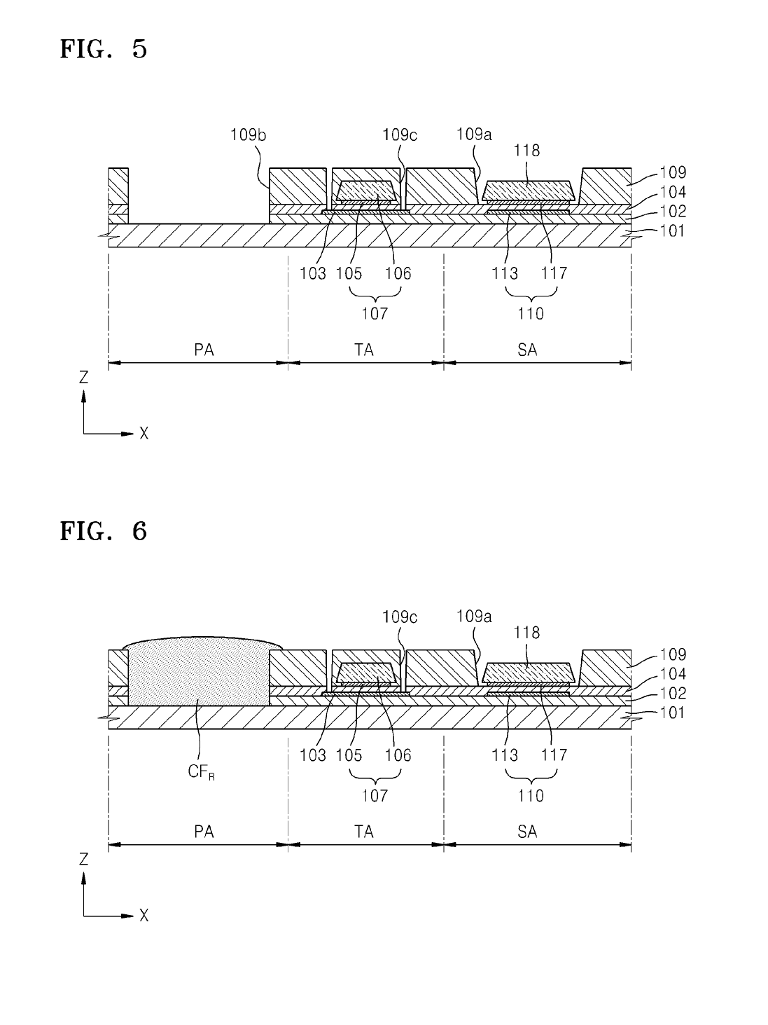

Thereafter, as shown in FIG. 5, the first insulating interlayer 109 is formed so as to cover the gate electrode 107. The first insulating interlayer 109 may include the first contact hole 109c for exposing a part of the active layer 103. Although not shown in FIG. 5, a plurality of the first contact holes 109c may be formed so as to correspond to a part of the active layer 103 about the gate electrode 107 as shown in FIG. 2. In addition, the first insulating interlayer 109 includes the opening portion 109a corresponding to the cover layer 118, and includes the opening 109b in the emission area PA.

The first insulating interlayer 109 may be formed on the majority of the entire surface of the substrate 101, and may be then patterned so as to form the first contact hole 109c, the opening portion 109a, and the opening 109b. That is, the first contact hole 109c, the opening portion 109a, and the opening 109b may be simultaneously formed. An opening may be formed in the buffer layer 102, the gate insulating layer 104, or the like below the first insulating interlayer 109 at the same time as when the opening 109b is formed, without being formed only in the first insulating interlayer 109.

Thereafter, as shown in FIG. 6, the color filter CF_{R} is formed within the opening 109b of the first insulating interlayer 109. A sub-pixel shown in FIG. 6 corresponds to a red sub-pixel, and thus the sub-pixel is shown to form the red color filter CF_{R}, a blue color filter, a green color filter, or the like may be formed in a blue sub-pixel, a green sub-pixel, or the like. The color filter CF_{R} may be formed using various methods, for example, an ink jet printing method.

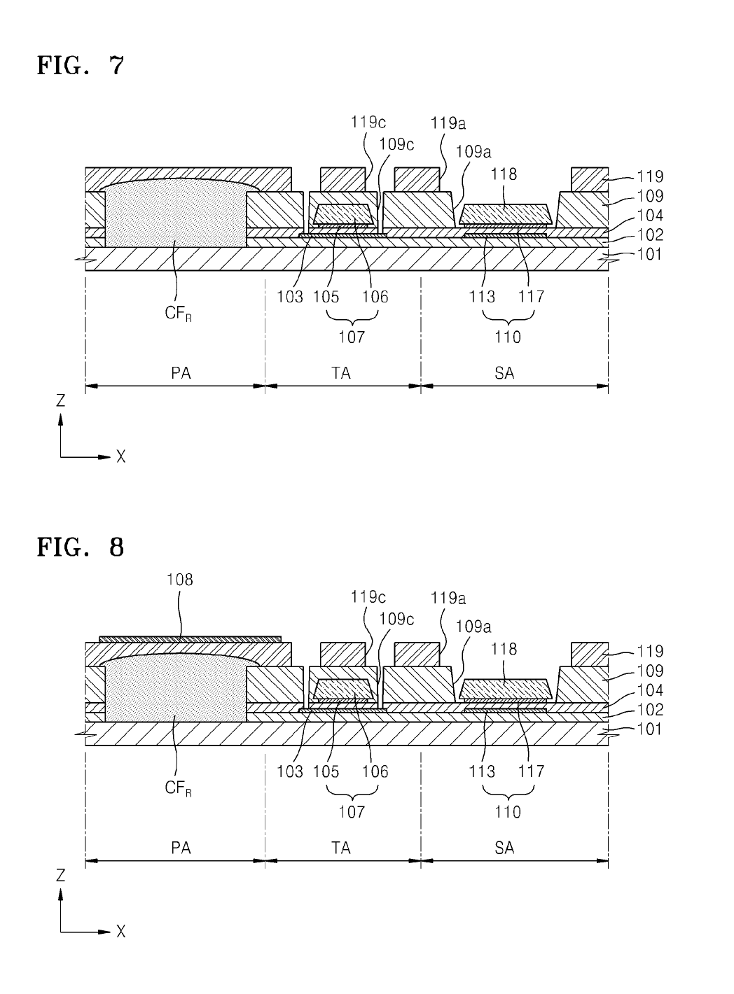

Subsequently, as shown in FIG. 7, the second insulating interlayer 119 is formed on the first insulating interlayer 109 so as to cover the color filter CF_{R}, and the second insulating interlayer 119 may include the second contact hole 119c connected to the first contact hole 109c. The second contact hole 119c may be formed to have a diameter or the like that is larger than that of the first contact hole 109c. In particular, when the first insulating interlayer 109 is formed of an inorganic material and the second insulating interlayer 119 is formed of an organic material, the first contact hole 109c may be easily formed to have a size that is smaller and more uniform than that of the second contact hole 119c. The second insulating interlayer 119 may include not only the second contact hole 119c but also the opening portion 119a that overlaps the top surface of the second capacitor electrode 117.

The second insulating interlayer 119 may be formed on the majority of the entire surface of the substrate 101, and may be then patterned so as to form the second contact hole 119c and the opening portion 119a. That is, the second contact hole 119c and the opening portion 119a may be simultaneously formed.

Thereafter, as shown in FIG. 8, the pixel electrode 108 is formed so that at least a part of the pixel electrode 108 is located in the emission area PA of the substrate 101. The pixel electrode 108 may be formed using various methods such as deposition, sputtering, or the like.

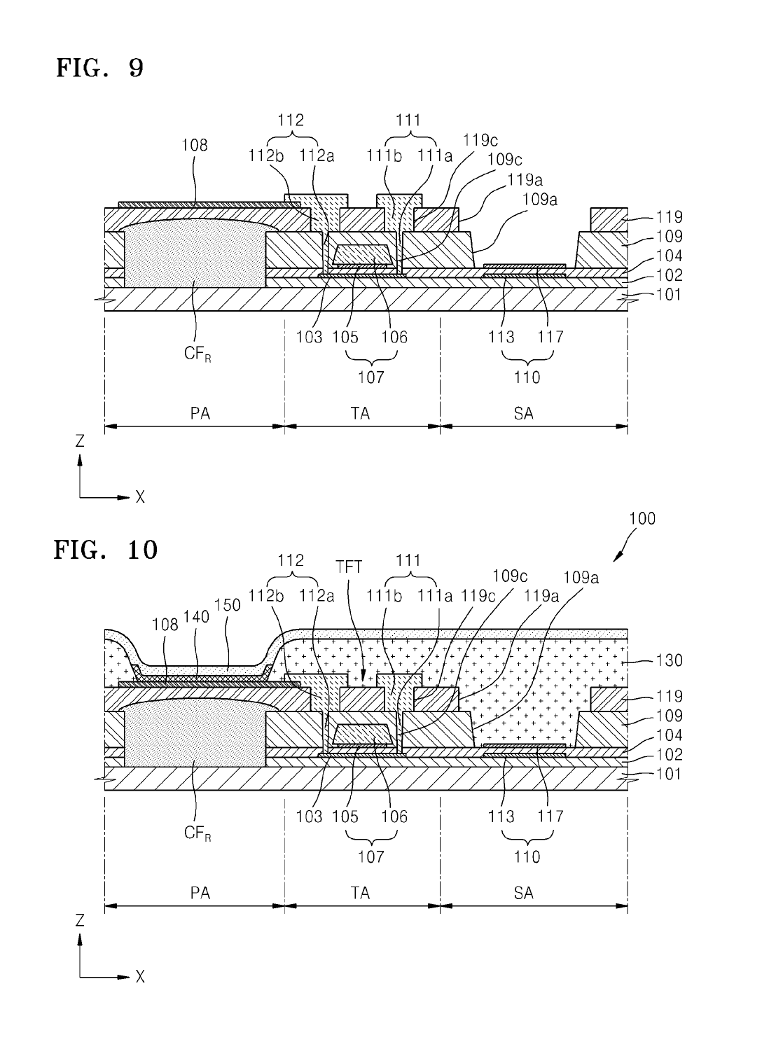

Then, as shown in FIG. 9, the source electrode 111 and the drain electrode 112 are formed. Specifically, the first source electrode layer 111a of the source electrode 111 and the first drain electrode layer 112a of the drain electrode 112 are formed so as to correspond to the first contact hole 109c of the first insulating interlayer 109, and the second source electrode layer 111b of the source electrode 111 and the second drain electrode layer 112b of the drain electrode 112 are formed so as to correspond to the second contact hole 119c of the second insulating interlayer 119. At least one of the source electrode 111 and the drain electrode 112 is formed so as to come into contact with the pixel electrode 108.

At this time, the first source electrode layer 111a, the first drain electrode layer 112a, the second source electrode layer 111b, and the second drain electrode layer 112b may be simultaneously formed through a patterning process using one mask. In this process, the first source electrode layer 111a and the first drain electrode layer 112a are naturally formed to be smaller than the second source electrode layer 111b and the second drain electrode layer 112b. In addition, in a case where the first contact holes 109c are formed as shown in FIG. 2, a plurality of the first source electrode layers 111a are connected to one second source electrode layer 111b, and a plurality of the first drain electrode layers 112a are connected to one second drain electrode layer 112b.

The first source electrode layer 111a, the first drain electrode layer 112a, the second source electrode layer 111b, and the second drain electrode layer 112b may be simultaneously formed by forming a conductive layer so as to correspond to the majority of the entire surface of the substrate 101 and by removing a part of the conductive layer through a photolithography method. In this process, the cover layer 118 on the second capacitor electrode 117 may also be removed. After the cover layer 118 is removed, a doping process of injecting impurities into the first capacitor electrode 113 via the second capacitor electrode 117 may be performed when necessary. In a state where the cover layer 118 is removed, the second capacitor electrode 117 is thin, and thus the first capacitor electrode 113 may be doped.

Alternatively, the pixel electrode 108 may be formed at the same time as when the source electrode 111 or the drain electrode 112 is formed when necessary, without having to be previously formed. For example, the pixel electrode 108 may be formed integrally with the drain electrode 112.

Thereafter, as shown in FIG. 10, the pixel definition layer 130 is formed on the second insulating interlayer 119 so as to cover the second source electrode layer 111b of the source electrode 111, the second drain electrode layer 112b of the drain electrode 112, and the second capacitor electrode 117. The pixel definition layer 130 may be formed so as not to cover at least a central portion of the pixel electrode 108.

Thereafter, the intermediate layer 140 including an emission layer, and the counter electrode 150 may be formed.

In the method of manufacturing the organic light-emitting display apparatus, the gate electrode 107 is formed, and then two insulating interlayers 109 and 119 are formed before forming the source electrode 111 and the drain electrode 112 so as to effectively prevent a short defect from occurring between the gate electrode 107 and the source electrode 111 and/or the gate electrode 107 and the drain electrode 112. Thus, the image quality of the organic light-emitting display apparatus 100 is improved.

In particular, the first contact hole 109c of the first insulating interlayer 109 is formed to be smaller than the second contact hole 119c so as to minimize an interval between the source electrode 111 and the drain electrode 112 and intervals between other wirings, thereby realizing the high-resolution organic light-emitting display apparatus 100. In addition, the second contact hole 119c of the second insulating interlayer 119 is formed to be larger than the first contact hole 109c, thereby improving an electrical property of the thin film transistor TFT. In addition, a plurality of the first contact holes 109c may be formed so as to be connected to one second contact hole 119c when necessary so as to improve an electrical property between the first source electrode layer 111a and the active layer 103 and an electrical property between the first drain electrode layer 112a and the active layer 103.

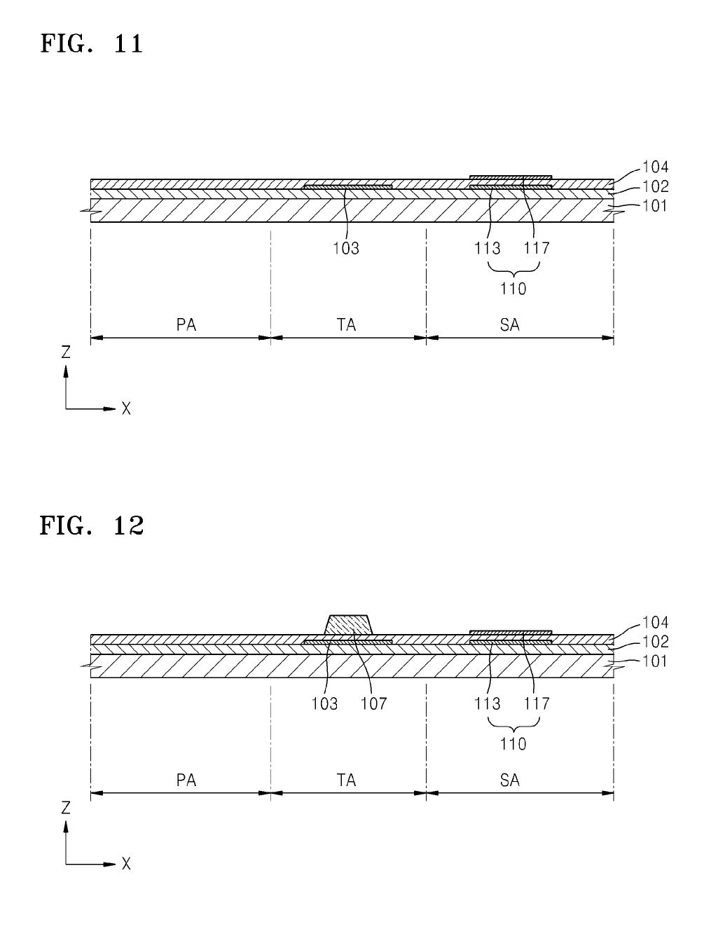

FIGS. 11 through 13 are schematic cross-sectional views illustrating processes of a method of manufacturing an organic light-emitting display apparatus according to another embodiment of the present invention. According to the method of manufacturing an organic light-emitting display apparatus, the gate insulating layer 104 is formed, and then the second capacitor electrode 117 is formed in the storage area SA, as shown in FIG. 11. In this process, a process of forming and patterning a conductive layer may be performed. Subsequently, as shown in FIG. 12, the gate electrode 107 is formed in the transistor area TA. In this process, a process of forming and patterning a conductive layer may be performed. The gate electrode 107 is formed to be thicker than the second capacitor electrode 117 so that the active layer 103 and the first capacitor electrode 113 are simultaneously doped but a portion that is blocked by the gate electrode 107 of the active layer 103 is not doped.

According to the method of manufacturing an organic light-emitting display apparatus, the gate electrode 107 and the first capacitor electrode 113 are separately formed, but the active layer 103 and the first capacitor electrode 113 are simultaneously doped, and thus the whole process does not become complicated.

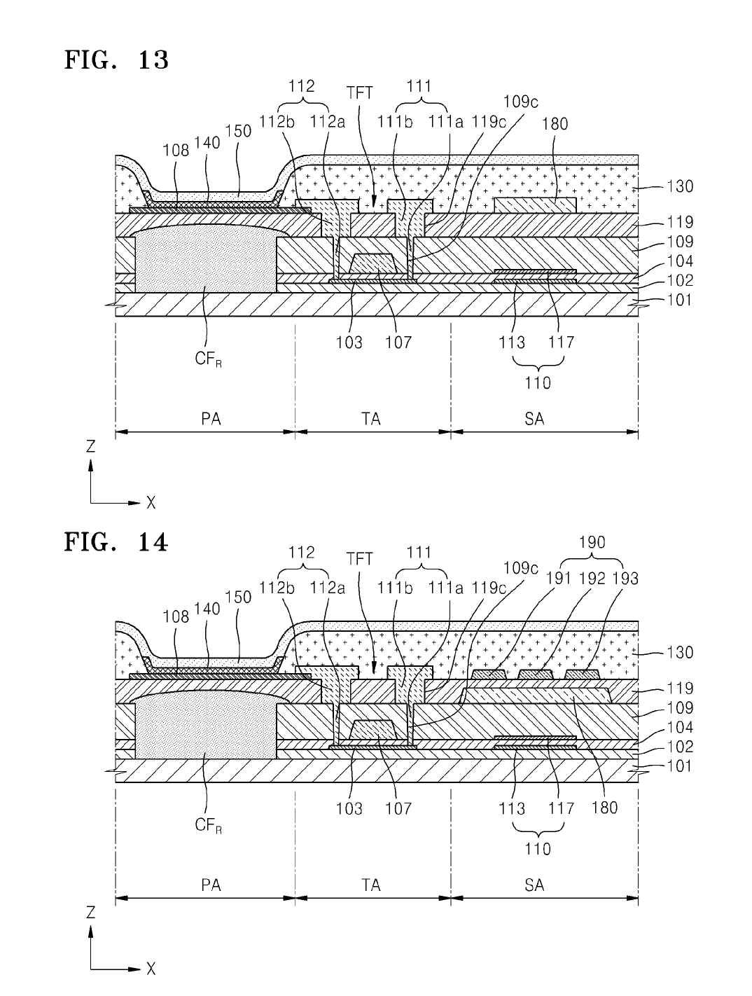

The subsequent process of forming the first insulating interlayer 109, the second insulating interlayer 119, the source electrode 111, the drain electrode 112, and the like as shown in FIG. 13 is similar to or the same as that in the method of manufacturing of an organic light-emitting display apparatus according to the above-described embodiment, and thus, a description thereof will not be repeated here.

A power wiring 180 located on the second insulating interlayer 119 may be formed in the storage area SA at the same time as when the source electrode 111 and the drain electrode 112 are formed in the transistor area TA. The power wiring 180 may be a wiring for supplying power necessary for emission in the emission area PA. The power wiring 180 may be formed so as to overlap the capacitor 110 of the storage area SA. Accordingly, an additional area for forming the power wiring 180 is not required, and thus the image quality may be improved by enlarging an aperture which is an area ratio of the emission area PA in the organic light-emitting display apparatus.

The organic light-emitting display apparatus shown in FIG. 13 which is manufactured in this manner may be construed as an organic light-emitting display apparatus according to another embodiment of the present invention.

FIG. 14 is a schematic cross-sectional view illustrating an organic light-emitting display apparatus according to another embodiment of the present invention. The organic light-emitting display apparatus is different from the organic light-emitting display apparatus according to the above-described embodiment in that the power wiring 180 is disposed on the first insulating interlayer 109. The power wiring 180 may be a wiring for supplying power necessary for emission in the emission area PA. The power wiring 180 may be formed so as to overlap the capacitor 110 of the storage area SA. Accordingly, an additional area for forming the power wiring 180 is not required, and thus the image quality may be improved by enlarging an aperture which is an area ratio of the emission area PA in the organic light-emitting display apparatus.

Meanwhile, a data wiring 190 may be disposed on the second insulating interlayer 119 when necessary, as shown in FIG. 14. In this case, the data wiring 190 may be formed of the same material as the source electrode 111 or the drain electrode 112, and may be formed at the same time as when forming the source electrode 111 or the drain electrode 112. Alternatively, the data wiring 190 may be formed of the same material as the pixel electrode 108, and may be formed at the same time as when forming the pixel electrode 108.

The data wiring 190 may transmit a data signal from a data driving unit (not shown) to the emission area PA via the transistor area TA. The data wiring 190 may be disposed so as to overlap the capacitor 110 of the storage area SA. In addition, the data wiring 190 may be disposed so as to overlap the power wiring 180.

FIG. 14 shows the data wiring 190 including a first data wiring 191, a second data wiring 192, and a third data wiring 193. In this case, the data wiring 190 corresponds to one pixel, and the first data wiring 191, the second data wiring 192, and the third data wiring 193 may be construed as corresponding to a plurality of sub-pixels included in one pixel. However, embodiments of the present invention is not limited thereto, and the data wiring corresponding to each sub-pixel may be disposed so as to correspond to the capacitor 110 and the power wiring 180. As another embodiment, the data wiring 190 may be formed on the first insulating interlayer 109, and the power wiring 180 may be formed on the second insulating interlayer 119.

According to embodiments of the present invention, it is possible to provide an organic light-emitting display apparatus that is capable of simplifying and facilitating a manufacturing process and has an improved image quality, and a method of manufacturing the organic light-emitting display apparatus. In addition, the scope of the present invention is not limited by these effects.

While the present invention has been particularly shown and described with reference to certain embodiments thereof, it will be understood by those of ordinary skill in the art that various changes in form and details may be made therein without departing from the spirit and scope of the present invention as defined by the following claims.

What is claimed is:

1. An organic light-emitting display apparatus comprising:
a substrate;
an active layer disposed on the substrate;
a gate electrode insulated from the active layer and configured to correspond to a part of the active layer;
a source electrode comprising a first source electrode layer connected to the active layer and a second source electrode layer connected to the first source electrode layer, the second source electrode layer being larger than the first source electrode layer;
a drain electrode comprising a first drain electrode layer connected to the active layer and a second drain electrode layer connected to the first drain electrode layer, the second drain electrode layer being larger than the first drain electrode layer;
a pixel electrode electrically connected to any one of the source electrode and the drain electrode; and
a color filter interposed between the substrate and the pixel electrode.

2. The organic light-emitting display apparatus of claim 1, further comprising:
a first insulating interlayer covering the gate electrode and having a first contact hole; and
a second insulating interlayer disposed on the first insulating interlayer and having a second contact hole.

3. The organic light-emitting display apparatus of claim 2, wherein the first source electrode layer and the first drain electrode layer correspond to the first contact hole, and the second source electrode layer and the second drain electrode layer correspond to the second contact hole.

4. The organic light-emitting display apparatus of claim 2, wherein a size of the first contact hole is smaller than a size of the second contact hole.

5. The organic light-emitting display apparatus of claim 2, wherein the first insulating interlayer comprises an inorganic material, and the second insulating interlayer comprises an organic material.

6. The organic light-emitting display apparatus of claim 2, wherein the first insulating interlayer has an opening corresponding to the pixel electrode, the color filter is located within the opening, and the pixel electrode is disposed on the second insulating interlayer.

7. The organic light-emitting display apparatus of claim 6, wherein a surface of the second insulating interlayer contacting the color filter has a concave shape toward the inside of the second insulating interlayer.

8. The organic light-emitting display apparatus of claim 2, wherein a top surface of the second insulating interlayer is planar.

9. The organic light-emitting display apparatus of claim 1, further comprising:
a first insulating interlayer covering the gate electrode and having a plurality of first contact holes; and
a second insulating interlayer disposed on the first insulating interlayer and having a second contact hole connected to the plurality of first contact holes.

10. The organic light-emitting display apparatus of claim 1, further comprising a capacitor comprising a first capacitor electrode and a second capacitor electrode that are both disposed on the substrate.

11. The organic light-emitting display apparatus of claim 10, further comprising:
a first insulating interlayer covering the gate electrode; and
a second insulating interlayer disposed on the first insulating interlayer,
wherein the first insulating interlayer and the second insulating interlayer each have an opening portion corresponding to the capacitor.

12. The organic light-emitting display apparatus of claim 10, further comprising at least one of a data wiring and a power wiring disposed on the capacitor and corresponding to the capacitor.

13. The organic light-emitting display apparatus of claim 12, wherein one or more insulating layers are interposed between at least one of the data wiring and the power wiring and the capacitor.

14. The organic light-emitting display apparatus of claim 12, further comprising:
a first insulating interlayer covering the gate electrode; and
a second insulating interlayer disposed on the first insulating interlayer,
wherein the first insulating interlayer and the second insulating interlayer are both interposed between the capacitor and the power wiring.

15. The organic light-emitting display apparatus of claim 10, further comprising a data wiring disposed on the capacitor and corresponding to the capacitor.

16. The organic light-emitting display apparatus of claim 15, wherein one or more insulating layers are interposed between the capacitor and the data wiring.

17. The organic light-emitting display apparatus of claim 15, further comprising:
a first insulating interlayer covering the gate electrode; and
a second insulating interlayer disposed on the first insulating interlayer,
wherein the first insulating interlayer and the second insulating interlayer are both interposed between the capacitor and the data wiring.

18. The organic light-emitting display apparatus of claim 10, further comprising a power wiring and a data wiring both disposed on the capacitor and corresponding to the capacitor, wherein the power wiring and the data wiring are disposed in different layers so as to overlap each other.

19. The organic light-emitting display apparatus of claim 18, further comprising:
a first insulating interlayer covering the gate electrode; and
a second insulating interlayer disposed on the first insulating interlayer,
wherein the power wiring is disposed on the first insulating interlayer, and the data wiring is disposed on the second insulating interlayer.

20. The organic light-emitting display apparatus of claim 18, further comprising:
a first insulating interlayer covering the gate electrode; and
a second insulating interlayer disposed on the first insulating interlayer,
wherein the data wiring is disposed on the first insulating interlayer, and the power wiring is disposed on the second insulating interlayer.

21. The organic light-emitting display apparatus of claim 10, wherein the first capacitor electrode and the active layer are disposed on the same layer, and the second capacitor electrode and the gate electrode are disposed on the same layer.

22. The organic light-emitting display apparatus of claim 1, wherein the pixel electrode is disposed on the same layer as at least a part of the second source electrode layer and at least a part of the second drain electrode layer.

23. The organic light-emitting display apparatus of claim 1, wherein the gate electrode comprises a first conductive layer and a second conductive layer disposed on the first conductive layer, and the first capacitor electrode comprises the same material as the first conductive layer and is disposed on the same layer as the first conductive layer.

24. A method of manufacturing an organic light-emitting display apparatus, the method comprising:
forming an active layer on a substrate;
forming a gate electrode configured to be insulated from the active layer and to overlap the active layer;
forming a color filter on the substrate;
forming a source electrode comprising a first source electrode layer connected to the active layer and a second source electrode layer connected to the first source electrode layer, the second source electrode layer being larger than the first source electrode layer;
forming a drain electrode comprising a first drain electrode layer connected to the active layer and a second drain electrode layer connected to the first drain electrode layer, the second drain electrode layer being larger than the first drain electrode layer; and
forming a pixel electrode electrically connected to any one of the source electrode and the drain electrode and corresponding to a color filter.

25. The method of claim 24, further comprising forming a first insulating interlayer having a first contact hole configured to cover the gate electrode, and a second insulating interlayer disposed on the first insulating interlayer and having a second contact hole.

26. The method of claim 25, wherein the forming of the source electrode and the forming of the drain electrode comprise forming the first source electrode layer and the first drain electrode layer so as to correspond to the first contact hole, and forming the second source electrode layer and the second drain electrode layer so as to correspond to the second contact hole.

27. The method of claim 25, wherein the forming of the source electrode and the forming of the drain electrode comprises simultaneously forming the first source electrode layer, the first drain electrode layer, the second source electrode layer, and the second drain electrode layer.

28. The method of claim 25, wherein the forming of the second insulating interlayer comprises:
forming a first insulating interlayer configured to cover the gate electrode;
forming a first contact hole configured to expose a part of the active layer and an opening corresponding to an area where the pixel electrode is to be formed, in the first insulating interlayer;
forming a second insulating interlayer configured to cover the first insulating interlayer; and
forming a second contact hole configured to expose a part of the active layer in the second insulating interlayer,
wherein the forming of the color filter comprises forming the color filter within the opening of the first insulating interlayer, and the forming of the second insulating interlayer comprises forming the second insulating interlayer so as to cover the color filter.
